(19) United States
(12) Patent Application Publication
(10) Pub. No.: US 2024/0330857 A1
(43) Pub. Date: Oct. 3, 2024

(54) VIRTUAL BUILDING CONSTRUCTION INSPECTION FOR PERMITTING

(71) Applicant: University of Florida Research Foundation, Inc., Gainesville, FL (US)

(72) Inventors: Ravi Shankar Srinivasan, Gainesville, FL (US); Nawari O. Nawari, Gainesville, FL (US)

(21) Appl. No.: 18/682,048

(22) PCT Filed: Aug. 8, 2022
(86) PCT No.: PCT/US2022/074657

§ 371 Date: Feb. 7, 2024

Related U.S. Application Data
(60) Provisional application No. 63/231,078, filed on Aug. 9, 2021.

(51) Int. Cl. G06Q 10/10; G06Q 50/16

(52) U.S. Cl. CPC G06Q 10/10; G06Q 50/165

(57) ABSTRACT

The present disclosure presents virtual building construction inspection systems and methods. One such method comprises storing, by a computing device, a first building information model (BIM) file for a building project, wherein the first BIM file comprises a building permit application file having a design for the building project; checking, by the computing device, the building permit application file for building code compliance with computable files defining building codes; generating, by the computing device, an output report indicating whether the building permit application file has passed a check for the building code compliance; and transmitting, by the computing device, the output report to a client device of an applicant associated with the building permit application file. Other systems and methods are also provided.

### CROSS-REFERENCE TO RELATED APPLICATION

This application claims priority to co-pending U.S. provisional application entitled, “VIRTUAL BUILDING CONSTRUCTION INSPECTION FOR PERMITTING,” having Ser. No. 63/231,078, filed Aug. 9, 2021, which is entirely incorporated herein by reference.

### TECHNICAL FIELD

The present disclosure is generally related to virtual building construction inspection.

### BACKGROUND

Many author have reported the benefits of Building Information Models (BIM) in the AEC (Architecture, Engineering & Construction) industry and have indicated that BIM has improved collaboration, cost-savings, project time schedules, have enhanced communications and data exchanges between different domains, and also have aided in the whole life cycle of a building. However, in spite of recent developments, the BIM workflow has several limitations. For example, there is no archival of BIM model modification history; there is no simple creation of relative deviation reports that compare design changes between different file versions; the current integrated BIM model is unsuitable for co-designing in real-time; there is a lack of communication standards and model sharing that can enable interoperability between different BIM toolsets; there is an inadequate tool or approach that can efficiently comment or mark upon Requests For Information (RFIs); there is the absence of legal structure describing model data proprietorship and legal matters; there are obstacles in allocating tasks and liabilities due to the overlap of responsibilities, certifying intellectual property, risk distribution, confidentiality, third-party dependence, and lack of software agents; most BIM platforms have time-consuming re-modeling, transformations, and other recurring tasks through the project phases that need to be automated; and lastly, the current BIM process has inadequate cyber-resilience of the process and software platforms, and thus, there are subsequent threats and liability to data theft, interfering, and other cyber-assaults.

### SUMMARY

Embodiments of the present disclosure provide virtual building construction inspection systems and methods. One such method comprises storing, by a computing device, a first building information model (BIM) file for a building project, wherein the first BIM file comprises a building permit application file having a design for the building project; checking, by the computing device, the building permit application file for building code compliance with computable files defining building codes; generating, by the computing device, an output report indicating whether the building permit application file has passed a check for the building code compliance; and/or transmitting, by the computing device, the output report to a client device of an applicant associated with the building permit application file.

Also disclosed herein is a system comprising at least one processor; and memory configured to communicate with the at least one processor, wherein the memory stores instructions that, in response to execution by the at least one processor, cause the at least one processor to perform operations comprising: storing a first building information model (BIM) file for a building project, wherein the first BIM file comprises a building permit application file having a design for the building project; checking the building permit application file for building code compliance with computable files defining building codes; conducting variance analysis of permitted plans and actual onsite construction phases; generating an output report indicating whether the building permit application file has passed a check for the building code compliance; and/or transmitting the output report to a client device of an applicant associated with the building permit application file.

In one or more aspects of such systems and methods, the computing device comprises a blockchain node, wherein the first BIM file is stored by the blockchain node in a blockchain network, wherein the building permit application file is checked for building code compliance in accordance with a smart contract of the blockchain network.

In one or more aspects, such systems and methods store, by the computing device, a second BIM file for the building project, wherein the second BIM file comprises a cloud point data file showing a progress in construction of the building project; and/or transmit, by the computing device, the second BIM file to a receiving computing device of an authority entity for review.

In one or more aspects, such systems and methods acquire mechanical, electrical, & plumbing (MEP) details of the building project from the first BIM file of the building project; acquire a current progress of the MEP details from the second BIM file of the building project; and/or check for current building code compliance by checking the MEP details of the building project with the current progress of the MEP details from the second BIM file. In one or more aspects of such systems and methods, the checking for current building code compliance comprises a Mechanical, Electrical, & Plumbing (MEP) engineering inspection; the checking for building code compliance comprises an architectural building inspection; the checking for building code compliance comprises a safety and hazard building inspection; and/or the checking and conducting operations are performed using artificial intelligence techniques performed by the at least one processor.

In one or more aspects of such systems and methods, the computing device comprises a blockchain node, wherein the first BIM file and the second BIM file are stored by the blockchain node in a blockchain network; the second BIM file further comprises thermal imaging data and/or LiDAR data and/or digital laser scanned and/or digital photographs of the building project.

In one or more aspects, such systems and methods acquire the cloud point data file and the thermal imaging data and/or LiDAR data and/or digital laser scanned and/or digital photographs data by flying a drone at the building project, wherein the drone is equipped with one or more cameras for acquiring cloud point data and the thermal imaging data and/or LiDAR data and/or digital laser scanned and/or digital photographs data of construction of structural and architectural elements of the building project. In one or more aspects, such systems and methods superimpose and visualize data of the second BIM file on a design model in 2D or 3D via the processor.

Other systems, methods, features, and advantages of the present disclosure will be or become apparent to one with skill in the art upon examination of the following drawings and detailed description. It is intended that all such additional systems, methods, features, and advantages be included within this description and be within the scope of the present disclosure.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIGS. 1A-1B show an overview of building permitting processes from conventional processes to an exemplary virtual permitting process in accordance with embodiments of the present disclosure.

FIG. 2 shows a top view of an exemplary UAV-based building construction inspection system in accordance with embodiments of the present disclosure.

FIG. 3 shows an overview of an exemplary Distributed Ledger Technology (DLT)-based Virtual Permitting Process (VPP) in accordance with embodiments of the present disclosure.

FIG. 4 shows a schematic block diagram of a computing device that can be used to implement various embodiments of the present disclosure.

### DETAILED DESCRIPTION

Building permits, in addition to traditional/manual review of plans and details for compliance with relevant building codes, ensure that proper visual inspections are performed on building project, and the inspections verify that construction of a building complies with code requirements. An exemplary virtual building construction inspection process may include several components and phases. First, drone(s) (or unmanned aerial vehicle(s)) can be used to perform drone-based virtual building inspection. Accordingly, drones can conduct automated fly-bys to inspect hard-to-reach areas/surfaces/spaces (e.g., roof fastener spacing/density, etc. and other anomalies) by a building inspector or specialist who possesses a license to fly drones. Additionally, point cloud and image captures can be obtained via the drone or by the inspector or specialist on the premises with a portable tablet or similar portable devices equipped with LiDAR, digital photography, Thermal InfraRed (TIR), or a digital laser scanner for visual inspection and compliance check with a progress of the building in comparison to the approved building permit requirements.

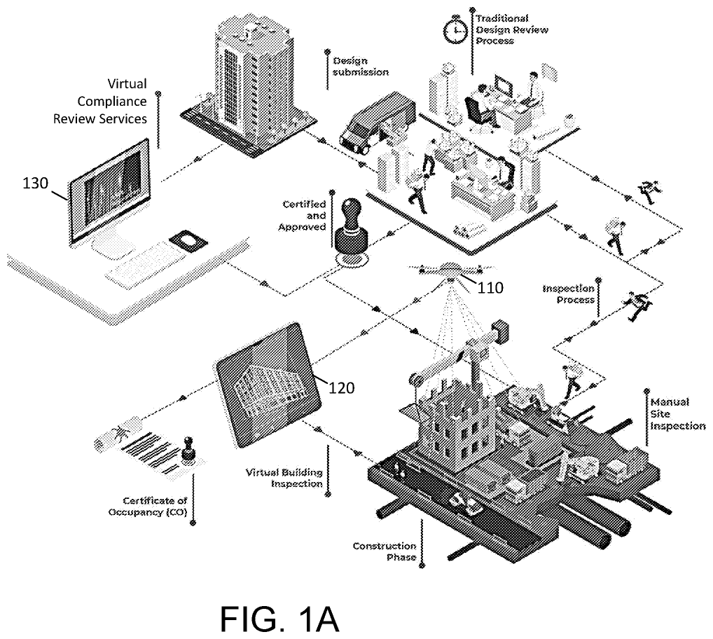

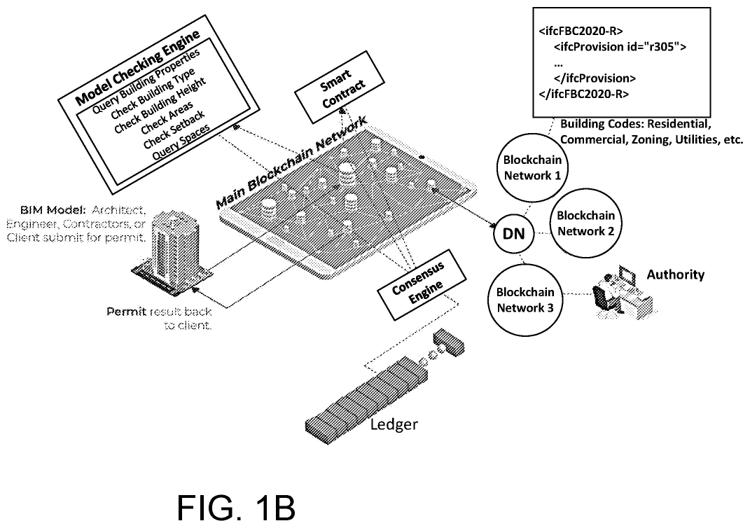

FIG. 1A shows an overview of building permitting processes from conventional processes to an exemplary virtual permitting process in accordance with embodiments of the present disclosure. Conventional permitting process generally require manual submissions, inspections, and/or reviews, which creates a slow permitting process for issuing building permits. Accordingly, traditional design review processes may take three to four weeks and often longer than that to finish the review and issue the building permit. These delays can cost money and can result in the loss of properties and/or life, such as in the situation where a building repair permits is not issued at the right time. For conventional design submissions, owner(s), contractor(s), architect(s), and/or engineer(s) need to submit the design drawings to the building authority to review them and make sure all the code regulations are followed. Building officials in each city and county may then start to manually review these drawings. After the local municipality issues the building permit, the construction phase can begin. During construction, the building authority will send the inspector to check each part of the construction to ensure that the approved drawings in the construction details are the same. This process is done in multiple phases: inspecting the building foundation; inspecting structural framing; inspecting architectural details such as walls, windows, doors, rooms, roofs, etc.; inspecting electrical wiring and equipment; inspecting plumbing; and inspecting mechanical systems. After each inspection phase, the building inspector updates the client about any variances. As such, the entire inspection process is timely and resource consuming.

However, an exemplary virtual permitting process can provide virtual submissions, inspections, and/or compliance reviews to create an improved and efficient process for issuing building permits. Accordingly, the present disclosure introduces a novel virtual inspection process where drones 110 and computer tablets 120 can be utilized to inspect the building and computing systems 130 can provide immediate feedback about deviations from the permitted design by comparing the physical constructed components with the authorities' approved BIM model as part of a compliance review.

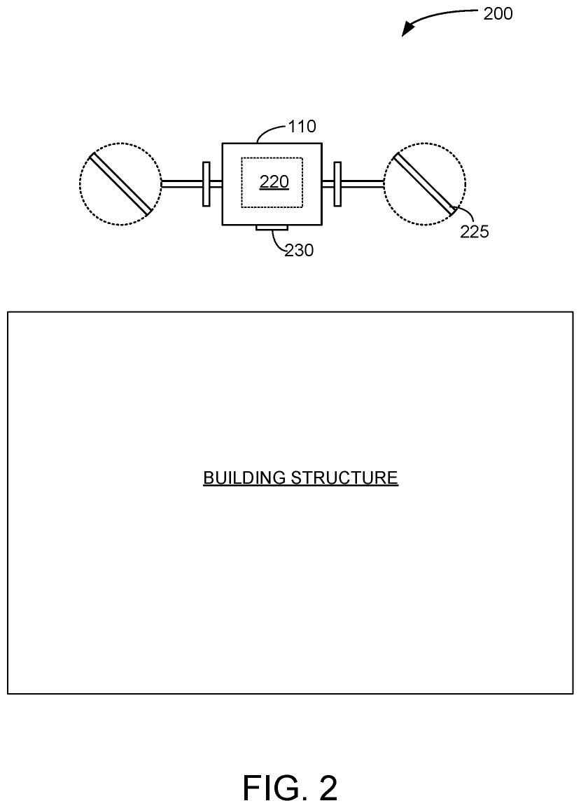

Referring to FIG. 2, a top view of an exemplary UAV-based building construction inspection system 200 is shown, in accordance with various embodiments of the present disclosure. For the system, an unmanned aerial vehicle 110 may be equipped with one or more control unit(s) 220 (e.g., that may include sensor controller(s), flight controller(s), global positioning system (GPS) circuitry, wireless transceiver units, sensor hardware, etc.). While the UAV vehicle is shown with two rotor blades 225 in FIG. 2, embodiments of the present disclosure are not limited to having two rotor blades and may have more than two rotor blades. A height that the UAV vehicle can reach during flight depends on the performance capability of the UAV vehicle (e.g., different models of UAV drones may have different performance capabilities). In certain implementations the cellular or network connectivity of the UAV 110 allows communication during acquisition of inspection data, enabling inspection data to be communicated to the control unit(s) 220 or other components and/or allowing the control unit(s) 220 to communicate with a remote base station or control unit. In various embodiments, one or more camera(s) 230 are equipped to the UAV vehicle 110 (e.g., a UAV base) and may be used for various applications, such as inspection applications. For example, in one embodiment, a camera 230 capable of infrared thermography (IRT) and/or hyperspectral imaging is provided to capture thermal infrared images, point cloud data (e.g., LiDAR), RGB color images, etc. After acquisition of camera images, the images can be stored in memory of the control circuitry 220 and/or transmitted, via the wireless transceiver, to a remote base station or computer device using one or more communication channels and protocols, including cellular, short range, WiFi communications, among others (see FIG. 1A).

In one embodiment, a structural steel rebar data capture from the point cloud and image captures (e.g., LiDAR, digital photography, Thermal InfraRed (TIR) images can be used to inspect, in a non-intrusive manner, engineering and structural features of the project being completed and compared to the permitted design. As discussed, an exemplary drone can be equipped with a thermal infrared imaging camera and LiDAR scanner (also referred to as “Integrated TIR and LiDAR” in this document). The resulting point cloud data captures can be used for compliance checking of the project with engineering and architectural specifications, such as truss design, beams and columns sizes, slab, foundation, walls, windows, roof, and other building structures' strength, etc. that is a non-intrusive. Similarly, integrated TIR and LiDAR-based point cloud data can also be generated for electrical systems (wiring), plumbing (water & wastewater), and supply/return air duct systems to compare with Mechanical, Electrical, & Plumbing (MEP) specifications and drawings. Likewise, integrated TIR and LiDAR-based point cloud data can also be captured for windows, doors' location, staircase (rise, tread, width, numbers), balustrades for comparison with design specs, room measurements, wall and ceiling heights per architectural drawings, roof decking thickness and other properties, fastener spacing data capture, etc. And, the integrated TIR and LiDAR-based point cloud data capture can be utilized to determine the variances between the actual construction and approved design via overlaying (superimposing) the data point model on the permitted BIM design model.

In various embodiments, an acquired point cloud data model can be superimposed on a BIM model of building design and visualized in 2D or 3D by permit officials via a computing device, including portable tablets 120, to check for compliance with applicable building rules and codes. In this way, permit officials/developer(s)/project manager(s) can perform onsite visual inspections and/or remote visual inspections using a tablet device. For example, a developer can perform a comparison of bill of materials, wastage quantities, etc. Additionally, systems and methods of the present disclosure can be used as support in training of AEC (Architecture, Engineering & Construction) professionals. Virtual inspections using the disclosed methods/systems can also identify potential safety or hazard concerns/issues (OSHA compliance) via the integrated TIR and LiDAR-based point cloud data captures.

In an exemplary embodiment, the captured or generated point cloud data model can be input into a BIM model (e.g., Autodesk Revit file) that can be used to compare the actual construction to the original approved permit drawings (e.g., a BIM model file format, such as an Autodesk Revit file) and allow for faster and more thorough inspection. In various embodiments, a distributed ledger technology (DLT) platform or network is used to store the BIM model data and associated algorithms on a secured distributed and encrypted platform.

In a typical distributed ledger technology (DLT) network, the entire processing and storage of data are performed in nodes that are hosted and supervised by local stakeholders. Also, the changes applied to the data are made implicitly immutable by appropriate cryptographic linking. This offers a sequential record of the following state(s) the data is in, along with the individual changes, in a transparent way. The progression over time can be recorded in more detail with the attachment of timestamps to individual modifications. DLT relies on consensus building, which refers to algorithms that enforce the data's validity and changes and replicated on multiple distributed nodes in the network.

Given the multi-disciplinary nature of a BIM project with teams who may belong to different organizations and considering other project participants with varying levels of functions and privileges, a permissioned DLT is most suitable for a collaborative BIM environment. Thus, in various embodiments, an exemplary blockchain network utilizes a Hyperledger Sawtooth (HLS) framework, among others, since it relies on a permissioned blockchain. A permissioned blockchain relies on the identities of its peers and provides a way to protected data exchanges between groups of entities who share a mutual goal, although they have intellectual properties that they need to secure while exchanging data. In various embodiments, the permissioned blockchain network can use the traditional Byzantine-fault tolerant (BFT) consensus mechanisms.

The Hyperledger Sawtooth (HLS) is based upon modular and extensible architectures. An example of exemplary modules that can be plugged in and implemented in Hyperledger include:
Membership services: This module deals with a permissioning and serves to create a root of trust during network formation. Also, this module is vital in managing the identity of members participating in the blockchain network. It provides a specialized digital certificate authority for issuing certificates to members of the BC network;
Chaincode services: A chaincode or smart contract is an application-level code stored on the ledger as a part of a transaction. Chaincode runs transactions that may modify the data on the ledger. Business logic is written as chaincode (often in the Go or Java languages). Chaincode is installed on network members machines, which require access to the asset states to perform reads and writes operations. The chaincode is then instantiated on particular channels for specific peers. Ledgers are normally shareable across entire networks of peers or include only a specific set of participants. Peers can participate in multiple BC (blockchain) channels;
Consensus services: These services are at the heart of any blockchain application. They enable a trust system. The consensus service permits digitally signed transactions to be proposed and validated by network members. The consensus is normally pluggable and tightly linked to the endorse-order validation model that the Hyperledger proposes. The ordering services in HLS represent the consensus system. The ordering service groups multiple transactions into blocks and outputs a hash-chained sequence of blocks containing transactions.

In various embodiments of an exemplary building construction inspection system, a DLT framework for virtual permitting process includes a main blockchain that connects to other external blockchain networks. The main network handles some of the key steps for an exemplary Virtual Permitting Process (VPP) in accordance with embodiments of the present disclosure. An exemplary DLT framework can store regulatory texts and BIM model data off-chain and facilitate the chaincode to function as a model checker algorithm (that verifies BIM model data, reports results to appropriate parties, and carries out other inspection-related duties in accordance with the present disclosure), such as conducting variance analysis of permitted (approved) plans and actual, onsite construction phases (e.g., during foundation, framing, etc.).

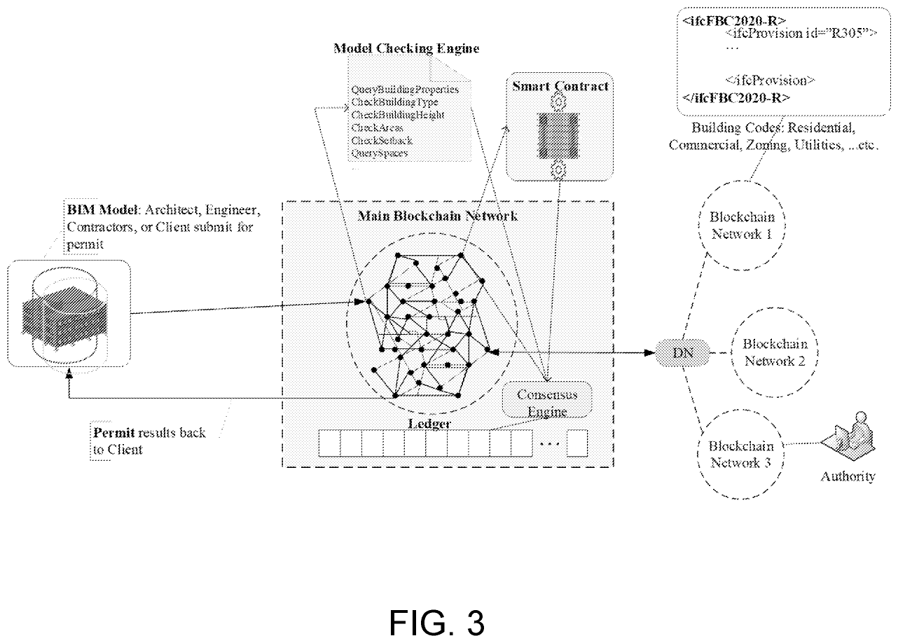

The details of this DLT-based VPP are shown in FIG. 3 and include:
(i) The building regulations upon which the BIM model data are to be assessed must be handled using computable expressions. A Smart Contract (chaincode) can be programmed to process the rules from a natural language using a Generalized Adaptive Framework (GAF) (Nawari, 2020). Additional details for an exemplary embodiment of the GAF framework and/or other components of the present application are provided in U.S. Provisional patent application, having Ser. No. 63,143,368, filed Jan. 29, 2021, which is entirely incorporated herein by reference. This chaincode can be implemented to incorporate all clauses, terms, and variables used in the building codes and regulations. Following the building regulations' transformation, the chaincode can generate a second appended smart contract that can be used by the model checker service;
(ii) The BIM model data, including point cloud data files, is stored in an ifcXML format smart contract platform. The BIM model data can be accessed by the model checker service using a smart contract (SC) (Python, Javascript, Rust, C++, and Go);
(iii) A model compliance checking service is programmed in the form of another chaincode that can extract data from the BIM model and, upon invoking, can verify the extracted data against the translated rules created in step (i);
(iv) The model checker invokes the code-checking process and creates another smart contract where the results are reported and sent to respective participants.
(v) The model compliance checking service executes SC to generate output reports to be sent to authorities to review and confirm the final permit status. Chief Authorities can be on a separate blockchain network to issue the building permit; and
(vi) To reliably connect with external blockchains, a secure gate of Decentralized Network (DN) can be utilized.

While Building Authorities in the US are still struggling to cope with the high demand for issuing building permits for new or alteration construction, automating or semi-automating the process reliably and securely offers a solution to this problem. The DLT is exemplified by a disseminated, decentralized ledger of data, resources, and data exchanges that have been processed and distributed among participants in a network system. Also, DLT offers immutable transparency, stresses reliability and trust between all participants on the network. Such characteristics can be beneficial in minimizing current limitations with the BIM-based permitting process.

Various DLT platforms are currently available for different applications. However, the Hyperledger Sawtooth (HLS) is highly suitable for enhancing the BIM-based building permitting process. These platforms are created with secure privacy in mind to ensure that various organizations and industries can take advantage of a DLT in different use-cases. A distinct feature of HLS is that it can sustain numerous ledgers within their network. This is a crucial aspect, which separates HLS from other DLT platforms.

An exemplary blockchain network framework aims to incorporate DLT using HLS with the BIM-based virtual permitting process to strengthen collaboration and trust, cybersecurity, responsibility, and data transaction integrity. The disclosed framework aims to reduce time to issue building permits and building inspection while maintaining transparency, trust, and accountability.

In various embodiments, an exemplary DLT-based framework for the Virtual Permitting Process (VPP) is based on the Generalized Adaptive Framework (GAF), Smart Contracts (Chaincode) for screening models and updating the ledger, model checking, and consensus engines, as illustrated in FIG. 1B. An exemplary DLT-based framework for VPP can expand the capabilities of the VPP by introducing secure identification and authentication of participants and establishes a ubiquitous and reliable infrastructure that serves as a repository for data storage, as well as a consistent platform that facilitates data exchanges during the virtual permitting process or virtual inspection. Key characteristics of DLT, such as using secure cryptography, asset sharing, examining trails of data access, immutability, and a robust peer-to-peer network, pose an innovative and promising approach to extending and augmenting the VPP.

As discussed, building permit review is the process of evaluating a proposed building design against its building codes and regulations to verify the quality and performance of the design and identify issues before construction takes place. Typically, counties and/or cities of the United States have one or more departments established to oversee building construction, where one can submit building documents, such as an application for a building permit (see FIG. 1A).

An exemplary method for automated inspection of building code conformance can automate a building construction permit compliance review process by having Applicants upload their building permit application file (as represented in a Building Information Model (BIM) data) to a blockchain network and comparing the uploaded file versus the state/local code and regulations and/or a subsequently acquired point cloud data model that has been input into a BIM model (e.g., an Autodesk Revit file) that can be used to compare the actual construction to the original approved permit drawings (e.g., a BIM model file format, such as an Autodesk Revit file) and allow for faster and more thorough inspection. This type of process can involve an interpretation process where the semantic structure of each regulation is translated into object rules or parametric models using certain formal languages and stored as a smart contract and associated with the Building Information Model (BIM) data being examined. With a building permit application having BIM data for a building or construction project, the BIM data can be used to extract relevant building details for a building that is modeled in BIM. In various embodiments, an exemplary building permit application having BIM data includes spatial relationships of the building design, quantities & properties of building components, and enables a wide range of building details that can be checked against applicable codes and regulations, since the BIM model defines objects as parameters and relations to other objects and carrying object attributes that specify pertinent details about the objects.

To start an exemplary building review process, an Applicant can upload a building permit application to a blockchain network, and the application can be prescreened to verify that the application is in the correct format, contact information is provided for the Applicant, or to verify other information that does not require detailed analysis or expert analysis of the contents of the application file. After the prescreening review is approved and completed, then the building permit application file can be analyzed in subsequent stages or phases of the review process in accordance with smart contract logic. As part of this analysis, a previously stored version of the building permit application file may be retrieved and compared against an updated version of the building application file, such as that containing a point cloud data model of an actual and constructed design of the respective building. Upon completion of the review and analysis, the Applicant may be notified by the blockchain that corrections are required and additional information will need to be reviewed or if the inspection or review has been approved, as depicted in the figure.

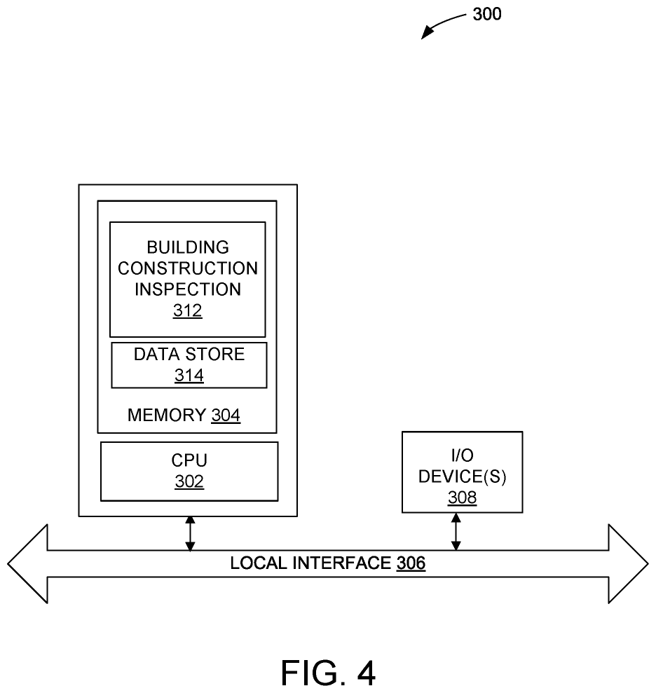

FIG. 4 depicts a schematic block diagram of a computing device 300 that can be used to implement various embodiments of the present disclosure. An exemplary computing device 300 includes at least one processor circuit, for example, having a processor (CPU) 302 and a memory 304, both of which are coupled to a local interface 306, and one or more input and output (I/O) devices 308. The local interface 306 may comprise, for example, a data bus with an accompanying address/control bus or other bus structure as can be appreciated. The CPU 302 can perform various operations described herein.

Stored in the memory 304 are both data and several components that are executable by the processor 302. In particular, stored in the memory 304 and executable by the processor 302 are code for implementing building construction inspection operations as described herein. Also stored in the memory 304 may be a data store 314 and other data. The data store 314 can include a database for Building Information Model (BIM) data, computable records of building codes & regulations, stored building permit applications, and potentially other data. In addition, an operating system may be stored in the memory 304 and executable by the processor 302. The I/O devices 308 may include input devices, for example but not limited to, a keyboard, mouse, communication adapters and/or transceivers, etc. Furthermore, the I/O devices 608 may also include output devices, for example but not limited to, a printer, display, etc.

Certain embodiments of the present disclosure can be implemented in hardware, software, firmware, or a combination thereof. If implemented in software, building construction inspection logic or functionality are implemented in software or firmware that is stored in a memory and that is executed by a suitable instruction execution system. If implemented in hardware, building construction inspection logic or functionality can be implemented with any or a combination of the following technologies, which are all well known in the art: discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc. It should be emphasized that the above-described embodiments are merely possible examples of implementations, merely set forth for a clear understanding of the principles of the present disclosure. Many variations and modifications may be made to the above-described embodiment(s) without departing substantially from the principles of the present disclosure.

For example, in accordance with various embodiments, systems and methods of the present disclosure enable virtual (building) permitting. Such systems/methods go beyond automated code compliance checking and, after critical reviews and final building inspection, will generate occupancy certificates. In an exemplary implementation, among others, a building permit officer can carry a portable computing device or tablet 120 loaded with visualization software (e.g., VRA Visualizer) that shows the various sections, plans, and compliance/non-compliance for site review/verification. Building permit officers can mark his/her comments while at the site, including capturing pictures at the site and attaching them to the comments, as necessary. This will also be helpful in building code development and enforcement.

In accordance with various embodiments, systems and methods of the present disclosure enable artificial intelligence (AI) review. Such systems/methods utilize the inputs gathered from model files and are configured to predict compliance and non-compliance by building types, area, and other characteristics (#of bedrooms, #of stairs, #of elevators). This will also be helpful in building code development and enforcement. Moreover, AI-based approaches can be configured to learn (supervised/unsupervised with penalties) and apply code reviews. Additional details for embodiments of the artificial intelligence functionality and/or other components are provided in U.S. Provisional patent application, having Ser. No. 63/143,368, filed Jan. 29, 2021, which is entirely incorporated herein by reference

In accordance with various embodiments, systems and methods of the present disclosure enable drone-based virtual building inspections. Such systems/methods utilize drones to conduct automated fly-bys to inspect hard-to-reach areas/surfaces/spaces by a building inspector (e.g., roof fastener spacing/density, etc. and other anomalies).

In accordance with various embodiments, systems and methods of the present disclosure enable engineering and structural building inspections. Such systems/methods utilize structural rebar data capture from point cloud and image captures (LiDAR, digital photography, and Thermal InfraRed or TIR images; also referred to as “Integrated TIR and LiDAR” in this document) for compliance; truss design, size, and comparisons with a building design. Non-intrusive sensor-based analysis of building structures can be performed, such as for the slab, foundation, and other building structures by captured data for compliance/comparison with engineering specifications.

In accordance with various embodiments, systems and methods of the present disclosure enable MEP engineering inspections. Such systems/methods can utilize integrated TIR and LiDAR-based point cloud data to generate electrical systems (wiring), plumbing (water & wastewater), and supply/return air duct systems to compare with MEP specifications/drawings, among others.

In accordance with various embodiments, systems and methods of the present disclosure enable architectural building inspections. Such systems/methods can utilize integrated TIR and LiDAR-based point cloud data capture for windows, doors' location, staircase (rise, tread, width, numbers), balustrades for comparison with design specifications; room measurements, wall and ceiling heights per architectural drawings, etc. Further, such systems/methods can utilize integrated TIR and LiDAR-based point cloud data capture after framing by overlaying or superimposing data on a design model to determine the variance and/or utilize captured data for compliance in assessing roof decking thickness and other properties, fastener spacing data capture, etc.

In accordance with various embodiments, systems and methods of the present disclosure enable safety/hazard building inspections. Such systems/methods can utilize integrated TIR and LiDAR-based point cloud data capture to identify safety/hazard issues (OSHA compliance).

In accordance with various embodiments, systems and methods of the present disclosure enable data visualization and exchange. Such systems/methods can check for non-compliance issues by overlaying or superimposing captured data on a design model and visualizing in 2D or 3D via a computing device (e.g., tablet device) by permit officials; support onsite permit official/developer/project manager visits (accessible via an exemplary computing device (e.g., tablet)); support developer staff to compare bill of materials, wastage quantities, etc.; support the training of AEC professionals, etc.

In accordance with various embodiments, systems and methods of the present disclosure enable a blockchain framework for virtual permitting and inspections. Such systems/methods can provide a building permitting blockchain network and/or a building virtual inspection blockchain network

All such modifications and variations are intended to be included herein within the scope of this disclosure.

Therefore, at least the following is claimed:

1. A method comprising:
storing, by a computing device, a first building information model (BIM) file for a building project, wherein the first BIM file comprises a building permit application file having a design for the building project;
checking, by the computing device, the building permit application file for building code compliance with computable files defining building codes;
generating, by the computing device, an output report indicating whether the building permit application file has passed a check for the building code compliance; and
transmitting, by the computing device, the output report to a client device of an applicant associated with the building permit application file.

2. The method of claim 1, wherein the computing device comprises a blockchain node, wherein the first BIM file is stored by the blockchain node in a blockchain network, wherein the building permit application file is checked for building code compliance in accordance with a smart contract of the blockchain network.

3. The method of claim 1, further comprising storing, by the computing device, a second BIM file for the building project, wherein the second BIM file comprises a cloud point data file showing a progress in construction of the building project.

4. The method of claim 3, further comprising transmitting, by the computing device, the second BIM file to a receiving computing device of an authority entity for review.

5. The method of claim 3, wherein the computing device comprises a blockchain node, wherein the first BIM file and the second BIM file are stored by the blockchain node in a blockchain network.

6. The method of claim 3, wherein the second BIM file further comprises thermal imaging data and/or LiDAR data and/or digital laser scanned and/or digital photographs of the building project.

7. The method of claim 6, further comprising acquiring the cloud point data file and the thermal imaging data and/or LiDAR data and/or digital laser scanned and/or digital photographs data by flying a drone at the building project, wherein the drone is equipped with one or more cameras for acquiring cloud point data and the thermal imaging data.

8. The method of claim 3, further comprising:
acquiring mechanical, electrical, & plumbing (MEP) details of the building project from the first BIM file of the building project;
acquiring a current progress of the MEP details from the second BIM file of the building project; and
checking for current building code compliance by checking the MEP details of the building project with the current progress of the MEP details from the second BIM file.

9. A system comprising:
at least one processor; and
memory configured to communicate with the at least one processor, wherein the memory stores instructions that, in response to execution by the at least one processor, cause the at least one processor to perform operations comprising:
storing a first building information model (BIM) file for a building project, wherein the first BIM file comprises a building permit application file having a design for the building project;
checking the building permit application file for building code compliance with computable files defining building codes;
conducting variance analysis of permitted plans and actual onsite construction phases;
generating an output report indicating whether the building permit application file has passed a check for the building code compliance; and
transmitting the output report to a client device of an applicant associated with the building permit application file.

10. The system of claim 9, wherein the first BIM file is stored in a blockchain network, wherein the building permit application file is checked for building code compliance in accordance with a smart contract of the blockchain network.

11. The system of claim 9, wherein the operations further comprise storing a second BIM file for the building project, wherein the second BIM file comprises a cloud point data file showing a progress in construction of the building project.

12. The system of claim 11, wherein the operations further comprise transmitting the second BIM file to a computing device of an authority entity for an inspection review.

13. The system of claim 11, wherein the first BIM file and the second BIM file are stored in a blockchain network, wherein the building permit application file is checked for building code compliance in accordance with a smart contract of the blockchain network.

14. The system of claim 11, wherein the second BIM file further comprises thermal imaging and/or LiDAR data and/or digital laser scanned and/or digital photographs data of the building project.

15. The system of claim 14, wherein the operations further comprise acquiring the cloud point data file and the thermal imaging and/or LiDAR data and/or digital laser scanned and/or digital photographs data by flying a drone at the building project, wherein the drone is equipped with one or more cameras for acquiring cloud point data and the thermal imaging and/or LiDAR data and/or digital laser scanned and/or digital photographs data of construction of structural and architectural elements of the building project.

16. The system of claim 11, wherein the operations further comprise:
superimposing and visualizing data of the second BIM file on a design model in 2D or 3D via the processor.

17. The system of claim 11, wherein the operations further comprise:
acquiring Mechanical, Electrical, & Plumbing (MEP) details of the building project from the first BIM file of the building project;
acquiring a current progress of the MEP details from the second BIM file of the building project; and
checking for current building code compliance by checking the MEP details of the building project with the current progress of the MEP details from the second BIM file.

18. The system of claim 17, wherein the checking for current building code compliance comprises a Mechanical, Electrical, & Plumbing (MEP) engineering inspection.

19. The system of claim 9, wherein the checking for building code compliance comprises an architectural building inspection.

20. The system of claim 9, wherein the checking for building code compliance comprises a safety and hazard building inspection.

21. The system of claim 9, wherein the checking and conducting operations are performed using artificial intelligence techniques performed by the at least one processor.
